(19) United States
(12) Patent Application Publication
(10) Pub. No.: US 2005/0248039 A1
(43) Pub. Date: Nov. 10, 2005

(54) Semiconductor device

(76) Inventors: Toshihiro Miura, Saku (JP); Iwamichi Kohjiro, Komoro (JP); Sakae Kikuchi, Yachiho (JP)

Correspondence Address: MILES & STOCKBRIDGE PC, 1751 PINNACLE DRIVE, SUITE 500, MCLEAN, VA, 22102-3833, US

(21) Appl. No.: 10/524,238

(22) PCT Filed: Sep. 30, 2002
(86) PCT No.: PCT/JP02/10177

§ 371 Date: Feb. 10, 2005

(51) Int. Cl. H01L 23/48

(52) U.S. Cl. 257/779

(57) ABSTRACT

A semiconductor device includes: a semiconductor chip having a plurality of pads formed on the main surface thereof; chip components having connection terminals formed on both ends thereof; a module board on which the semiconductor chip and the chip components are mounted; solder connection portions for connecting the chip components to the terminals of the module board and connecting the semiconductor chip to the module board by solder; gold wires for connecting pads of the semiconductor chip to terminals of the module board corresponding thereto; and a sealing section which covers the semiconductor chip, the chip components, solder connection portions and gold wires and is formed of an insulating elastic resin such as silicone resin, wherein the wire height is set to 0.2 mm or less and the wire length is set to 1.5 mm or less so as to prevent the gold wires from being broken.

### TECHNICAL FIELD

The present invention relates to a semiconductor manufacturing technology, and in particular, it relates to a technology effectively applicable to a radio frequency module.

### BACKGROUND ART

As an example of a module product (semiconductor device) in which surface-mounted chip components such as chip capacitors and chip resistors and semiconductor chips to be mounted as bear chips are mounted, a so-called radio frequency module (also referred to as RF module or RF power module) has been developed, in which the chip components and the semiconductor chips are connected to a module board by solder, and both are covered with insulating resin for protection.

Note that Japanese Patent Application Laid-Open Nos. 2000-223623 and 2002-208668 describe the structure in which chip components (surface-mounted components) and the semiconductor chips are mounted and both are covered with resin.

First, Japanese Patent Application Laid-Open No. 2000-223623 describes a technology as follows. That is, the elastic modulus of a first resin which covers wire-bonded semiconductor chips and wires thereof is set higher than that of a second resin which covers the outside of the first resin to make the first resin harder than the second resin. As a result, the deformation of the first resin caused by thermal stress can be reduced and the breakage of the wires can be prevented.

Also, Japanese Patent Application Laid-Open No. 2002-208668 describes a technology as follows. That is, surface-mounted components mounted by solder and solder connection portions thereof are covered with a low elastic resin with an elastic modulus of 200 MPa or lower at 150° C. or higher. By doing so, even when the semiconductor device is mounted by using the secondary reflow and the inner solder connection portions are remelted, the pressure caused by the expansion of the melted inner solder connection portions can be reduced by the low elastic resin, which prevents solder from flowing into an interface between the surface-mounted components and resin, thereby preventing a short-circuit between terminals of the surface-mounted components.

The inventors have found the following problems with respect to the semiconductor device having the above-described structure in which the chip components (surface-mounted components) and the semiconductor chips are mounted and both are covered with resin.

More specifically, when covering the surface-mounted components and solder connection portions thereof with the low elastic resin as described in Japanese Patent Application Laid-Open No. 2002-208668, wires are broken by the stress caused by thermal shrinkage of the low elastic resin during a thermal cycle test for a semiconductor device.

In Japanese Patent Application Laid-Open No. 2002-208668, nothing has been mentioned about the breakage of wire, although the inventors have found that the breakage of wire is correlative with the loop height and length of the wire.

In Japanese Patent Application Laid-Open No. 2000-223623, a technology for preventing wires from being broken has been described, but nothing has been mentioned about the loop height and length of the wire.

An object of the present invention is to provide a semiconductor device capable of preventing a bonding wire from being broken.

Another object of the present invention is to provide a highly reliable semiconductor device.

The above and other objects and novel characteristics of the present invention will be apparent from the description and the accompanying drawings of this specification.

### DISCLOSURE OF INVENTION

A semiconductor device according to the present invention comprises: a semiconductor chip; a wiring board over which the semiconductor chip is mounted; a plurality of bonding wires for connecting surface electrodes of the semiconductor chip to terminals of the wiring board corresponding thereto; and a sealing section in which the semiconductor chip and the plurality of bonding wires are covered and sealed with resin, the sealing section being formed of an insulating elastic resin, wherein the elastic resin has an elastic modulus of 1 to 200 MPa at a temperature of 150° C. or higher, and a height of the bonding wire from a main surface of the semiconductor chip to a top of the bonding wire is 0.2 mm or less.

A semiconductor device according to the present invention comprises: a semiconductor chip; a wiring board over which the semiconductor chip is mounted; a plurality of bonding wires for connecting surface electrodes of the semiconductor chip to terminals of the wiring board corresponding thereto, the bonding wire having a height of 0.2 mm or less from a main surface of the semiconductor chip to a top of the wire; and a sealing section in which the semiconductor chip and the plurality of bonding wires are covered and sealed with resin, the sealing section being formed of an insulating elastic resin with an elastic modulus of 1 to 200 MPa at a temperature of 150° C. or higher, wherein the semiconductor device is connected to a mounting board by solder.

### BRIEF DESCRIPTION OF THE DRAWINGS

FIG. 1 is a plan view showing the structure of a radio frequency module as an example of the semiconductor device according to an embodiment of the present invention;

FIG. 2 is a side view showing the structure of the radio frequency module shown in FIG. 1;

FIG. 3 is a bottom view showing the structure of the radio frequency module shown in FIG. 1;

FIG. 4 is a side view showing the structure of the radio frequency module viewed from the arrow A shown in FIG. 1;

FIG. 5 is a plan view illustrating an example of the layout of surface-mounted components of the radio frequency module shown in FIG. 1;

FIG. 6 is a partial sectional view showing the structure taken along the line B-B shown in FIG. 5;

FIG. 7 is a sectional view showing an example of the allowable range of bonding wires for the radio frequency module shown in FIG. 1;

FIG. 8 is an enlarged partial sectional view showing an example of the solder connection structure of the chip components shown in FIG. 6;

FIG. 9 is a characteristic diagram showing an example of the temperature characteristics of low elastic resin used for a sealing section of the radio frequency module shown in FIG. 1;

FIG. 10 is an evaluation-result table showing an example of the number of cracks in the evaluation of the wire height of the radio frequency module shown in FIG. 1;

FIG. 11 is an evaluation-result table showing an example of the number of broken wires in the evaluation of the wire height of the radio frequency module shown in FIG. 1;

FIG. 12 is a partial enlarged view showing an example of wire crack in the radio frequency module shown in FIG. 1;

FIG. 13 is a data distribution map showing an example of the evaluation of the wire cracks and broken wires in the radio frequency module shown in FIG. 1;

FIG. 14 is a partial enlarged view showing an example of the broken wire in the radio frequency module shown in FIG. 1;

FIG. 15 is a partial enlarged side view showing an example of the structure in which the radio frequency module shown in FIG. 1 is mounted on a mounting board; and

FIGS. 16 to 22 are partial enlarged sectional views showing the structures of the radio frequency modules in the modified examples of the embodiment of the present invention.

### BEST MODE FOR CARRYING OUT THE INVENTION

In the embodiment described below, the description of the same and similar parts are not repeated in principle except for when needed in particular.

Also, in the embodiment described below, when referring to the number of an element (including number of pieces, values, amount, range, and the like), the number of the element is not limited to a specific number unless otherwise stated or except the case where the number is apparently limited to a specific number in principle. The number larger or smaller than the specified number is also applicable.

Further, in the embodiment described below, it goes without saying that the components (including element steps) are not always indispensable unless otherwise stated or except the case where the components are apparently indispensable in principle.

Similarly, in the embodiment described below, when the shape of the components, positional relation thereof, and the like are mentioned, the substantially approximate and similar shapes and the like are included therein unless otherwise stated or except the case where it can be conceived that they are apparently excluded in principle. This condition is also applicable to the numerical value and the range described above.

Hereinafter, an embodiment of the present invention will be described in detail with reference to the accompanying drawings. Note that components having the same function are denoted by the same reference symbols throughout the drawings for describing the embodiment, and the repetitive description thereof is omitted.

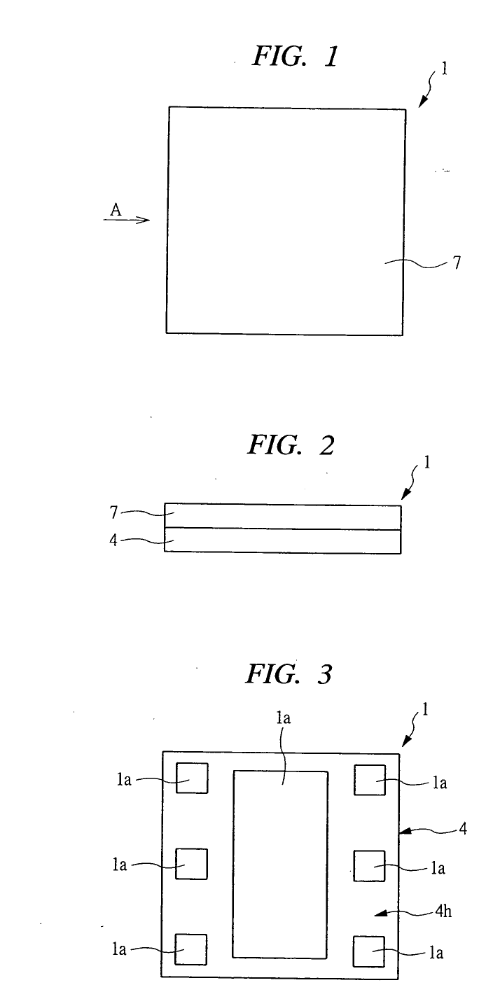

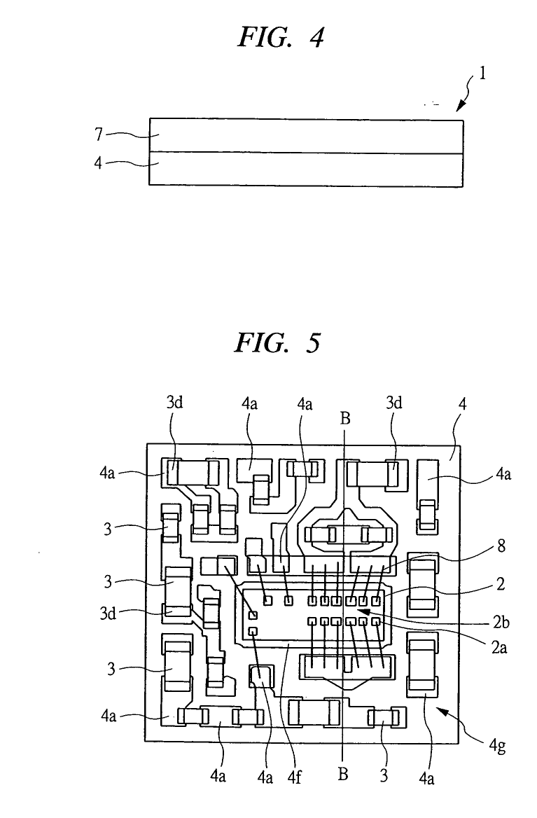

The semiconductor device according to this embodiment shown in FIGS. 1 to 4 is a module product called a radio frequency module 1. The module has such a structure that components are mounted on a module board 4 by solder and covered with sealing resin, and it is mainly built in small mobile electronic equipment such as cellular phone and others.

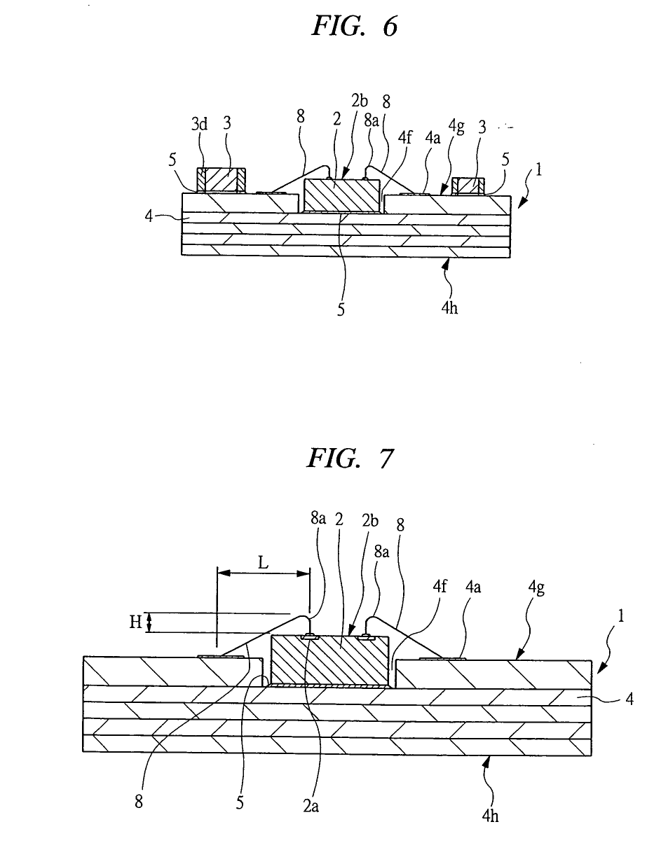

As shown in FIG. 5, the radio frequency module 1 in this embodiment comprises: a semiconductor chip 2 that is a mounted component having a plurality ofpads (surface electrode) 2a formed on its main surface 2b; chip components 3 that are mounted components having connection terminals 3d formed on both ends thereof; a module board 4 that is a wiring board on which the semiconductor chip 2 and the chip components 3 are mounted; a solder connection portion 5 shown in FIG. 6 where the chip component 3 is connected to the terminal 4a of the module board 4 by solder and the semiconductor chip 2 is connected to the module board 4 by solder; gold wires 8 that are bonding wires for connecting pads 2a of the semiconductor chip 2 to corresponding terminals 4a of the module board 4; and a sealing section 7 shown in FIG. 2 which covers the semiconductor chip 2, the chip components 3, the solder connection portion 5 and the gold wires 8, and is formed of elastic resin such as insulating silicone resin.

In the radio frequency module 1, since the chip components 3 soldered on the module board 4 are covered with a low elastic resin such as silicone resin, it is possible to weaken the pressure caused by the expansion of solder remelted at the solder connection portion 5 during the secondary reflow process (reflow on the mounting board performed by customers). This prevents the separation at the interfaces between the chip component 3 and the sealing section 7 and between the sealing section 7 and the module board 4, and therefore, it is possible to prevent the solder from flowing into the interfaces.

Further, since the low elastic resin is used, in order to prevent the gold wire 8 from being broken by the stress of the elastic resin generated in the thermal cycle test for the radio frequency module 1, ranges are given to the height and length of the wire loop 8a of the gold wire 8.

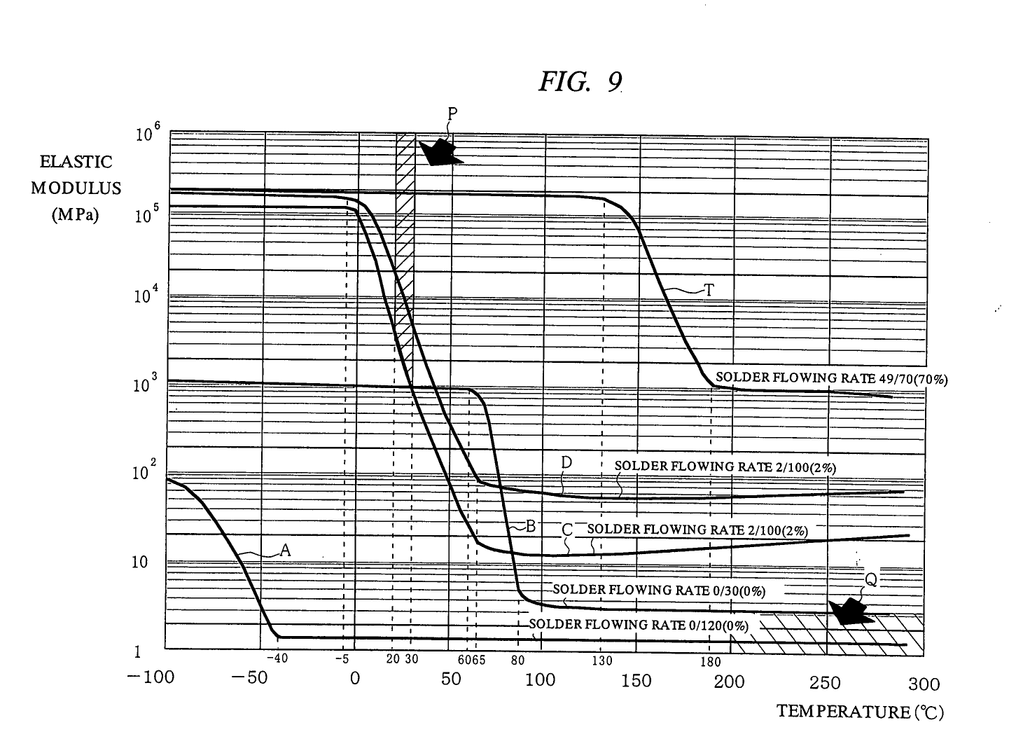

The elastic resin which forms the sealing section 7 is a low elastic and insulating resin having both of a strength capable of protecting internal components (mechanical strength) and a flexibility capable of weakening a pressure caused by the expansion of remelted inner solder. A silicone resin (silicone rubber) A, low-elastic epoxy resins B, C, and D having elastic moduli shown in FIG. 9 are preferable, and a conventional high-elastic epoxy resin T is unsuitable.

The allowable range of elastic modulus of the elastic resins (resin A, B, C, and D shown in FIG. 9) in this embodiment is preferably 200 MPa or lower at a temperature of 150° C. or higher in consideration of conditions under which they are subjected to high temperatures, that is, the temperature of the secondary reflow process (about 230° C. in general), or the temperature cycle test (for example, −40° C. to +125° C.)

This allowable range is obtained with reference to FIG. 9 based on the elastic moduli that can weaken the pressure caused by the expansion of the remelted solder of the solder connection portion 5 inside the radio frequency module 1 at the high temperature of 150° C. or higher. In FIG. 9, the resins A, B, C, and D are within the range, but the resin T is not within the range and is unsuitable.

Further, it is preferable that the elastic resin has an elastic modulus of 1 MPa or higher at the temperature of 150° C. or higher, and the resins A, B, C, and D are within the range as shown in FIG. 9.

This range is obtained in consideration of the result of the test for protecting surface-mounted components inside the sealing section 7. The result has proven that the elastic resin with an elastic modulus of at least 1 MPa or higher is capable of protecting the inner components.

A more preferable elastic modulus is 5 to 10 MPa at the temperature of 150° C. or higher.

Also, even at a temperature where the resin is actually used (a normal temperature of 25° C.), an elastic modulus of at least 1 MPa or higher is required, and the resins A, B, C, and D are within the range as shown in FIG. 9.

In addition, it is more preferable that the elastic resin has an elastic modulus of 200 MPa or higher at the temperature where the resin is actually used (normal temperature of 25° C.) so as to enhance a protection effect of the surface-mounted components, and the resins B, C, and D are within the range, but the resin A is not within the range as shown in FIG. 9.

The resin A, however, has no particular problem because it has an elastic modulus of 1 MPa or higher.

In FIG. 9, the term “solder flowing rate” of each resin means the number of defectives and occurrence rate of the defectives (%) in the electrical short-circuit test for the chip component 3 performed during the reflow at 260° C. The denominator represents the number of tests and the numerator represents the number of defectives.

As can be understood from FIG. 9, the resins A, B, C, and D have an extremely low defective occurrence rate of 0 to 2%, but the resin T determined to be unsuitable has a very high defective occurrence rate of 70%.

As described above, when the silicone resin (resin A), for example, is used as the elastic resin, the best range of an elastic modulus is 2 to 4 MPa in an overall consideration of the reflow temperature margin and the mechanical strength (protecting strength) of the radio frequency module 1.

In other words, when the silicone resin (resin A) is used, the best range of the rubber hardness is a Shore hardness of 70 A to 80 A in an overall consideration of the reflow temperature margin and the mechanical strength (protecting strength) of the radio frequency module 1.

Incidentally, an area P (striped area) indicates the best area in the segmentation of the elastic resin when dividing a multi-chip substrate into segments during the fabrication process of the radio frequency module 1, and an area Q (striped area) indicates a safety area in reflow-resistance of the elastic resin.

Also, the low-elastic epoxy resins B, C, and D shown in FIG. 9 have a different content of, for example, silica included respectively. They are therefore a little different in their characteristics.

Next, a loop height of the gold wire 8 (hereinafter referred to as a wire height) and a length of the gold wire 8 (hereinafter referred to as a wire length) in the radio frequency module 1 in this embodiment will be described.

First, as shown in FIGS. 5 and 6, a concave cavity 4f, in which the semiconductor chip 2 is disposed, is formed in the surface 4g that is one surface of the module board 4 on which components are mounted. Since the semiconductor chip 2 is disposed in the concave cavity 4, the height of the radio frequency module 1 can be lowered.

Further, the pads 2a of the semiconductor chip 2 are connected to the corresponding terminals 4a of the module board 4 with the gold wires 8, and a wire loop 8a is formed on each of the gold wires 8.

As shown in FIG. 7, the wire height H is the distance from the main surface 2b of the semiconductor chip 2 to the top of the wire loop 8a (to the outer line of the gold wire 8). However, in the case where the first bonding is made on a place different from on a chip (for example, the terminal 4a on the module board 4), the wire height H is the distance from a bonding start point (first bonding point) to the top of the wire loop 8a.

Also, the wire length L is the distance of the gold wire 8 projected onto the horizontal plane (horizontal distance of the wire) from the bonding start point (first bonding point) to the bonding end point (second bonding point). That is, the wire length L is a distance projected onto the horizontal plane from the center of the wire at the start point to that of the wire at the end point.

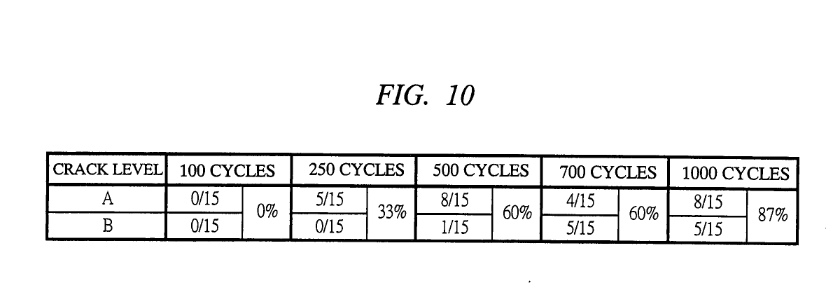

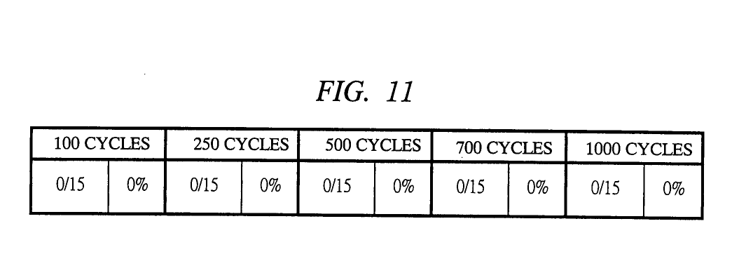

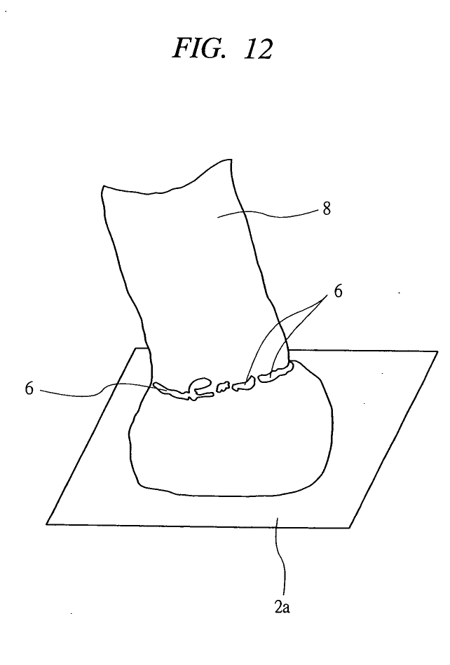

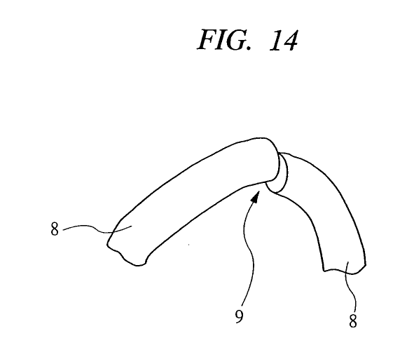

FIGS. 10 and 11 show states of the gold wire 8 in the heat cycle tests (−55° C. to 150° C.). FIG. 10 shows the number of occurrences of crack 6 (refer to FIG. 12). FIG. 11 shows the number of occurrences of broken wire 9 (refer to FIG. 14).

Note that a crack level A in FIG. 10 refers to the occurrence of the crack 6 of less than 50% around the wire, and a crack level B refers to the occurrence of the crack 6 of 50% or more around the wire.

As shown in FIG. 10, the crack 6 begins to occur at 250 cycles and occurs more often as the number of cycles increases, and it can be understood that the gold wire 8 is degraded as time passes.

Also, as shown in FIG. 11, the broken wire 9 is not found even after a heat test of 1,000 cycles.

FIG. 14 illustrates the state where the wire is subjected to the heat cycle test (−55° C. to 150° C.) under the conditions that the wire height is 0.22 mm (220 μm) and the wire length is 1.8 mm, and the broken wire 9 is seen in it.

In the radio frequency module 1 in this embodiment, the ranges of the wire height and the wire length are set so as to prevent the gold wire (bonding wire) 8 from being broken (broken wire 9) due to the stress of the elastic resin.

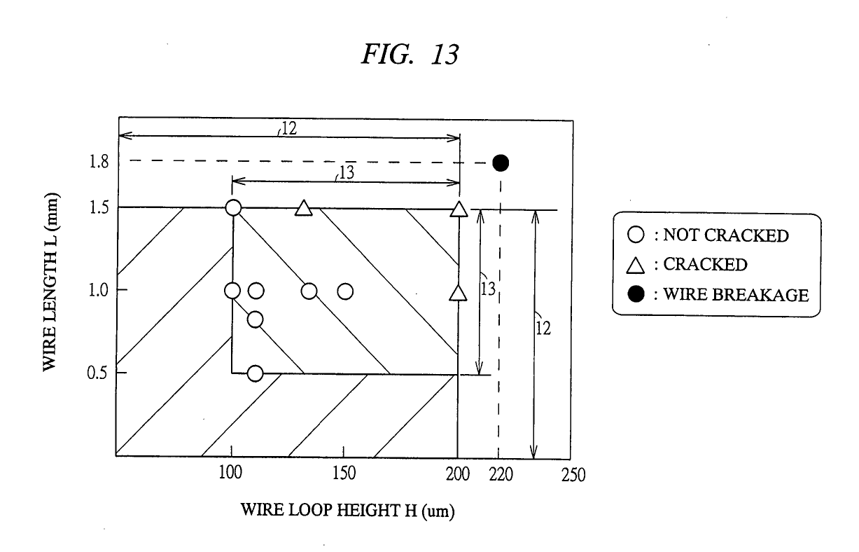

FIG. 13 shows distribution of data for cracks and broken wire obtained after a heat cycle test of 1,000 cycles. This figure shows that the wire cracks occur frequently in the case where the wire height is 0.2 mm (200 μm) and a wire length is 1.5 mm. It is presumable that the longer the length and the higher the height than those, the higher the occurrence rate of the wire cracks becomes and the higher the potential of the broken wires 9 as shown in FIG. 14 becomes.

For this reason, the wire height of 0.2 mm (200 μm) or lower and the wire length of 1.5 mm or shorter are set to a presumed safety range 12. Also, in view of restraints of a wire bonding device, the wire height of 0.1 or higher to 0.2 mm and the wire length of 0.5 mm or longer to 1.5 mm are set to a manufacturing target range 13.

Note that an example of practical target product has the wire height of 0.16 mm (160 μm) and wire length of 1.2 mm.

In this manner, the radio frequency module 1 according to this embodiment can prevent the occurrence of the broken wire 9 of the gold wire 8.

Also, since the wire height is lowered and the wire length is shortened, it is possible to prevent the wire from drooping and contacting to neighboring wires.

Further, it is also possible to prevent the wires from being deformed and contacting to neighboring wires due to the flow of resin when molding the resin.

In addition, since the wire height is lowered and the wire length is shortened, it is possible to decrease the quantity of the elastic resin flowing into the lower part of the wire. Therefore, the physical volume of expansion and shrinkage of the elastic resin can be reduced. As a result, the product reliability concerning the thermal stress can be improved.

Next, a solder to be used in the radio frequency module 1 according to this embodiment will be described.

First, the module board 4 is formed of, for example, alumina ceramic, and a plurality of external terminals 1a are provided on both the surface 4g and the rear surface 4h thereof as shown in FIG. 3.

Also, chip components 3 such as ceramic chip capacitors, chip resistors, or chip thermisters are mounted on the surface 4g in addition to the semiconductor chip 2. The connection terminals 3d on both ends of the mounted components are connected to the terminals 4a of the module board 4 via respective solder connection portions 5.

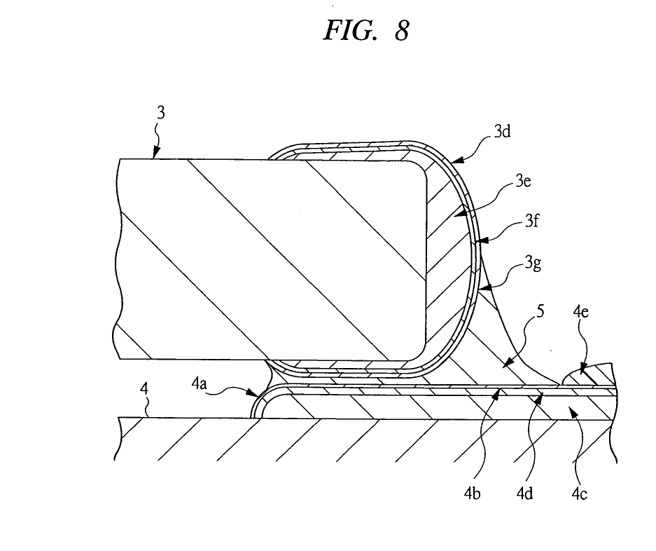

In this point, since the semiconductor chip 2 is wire-bonded by using the gold wires 8, the gold plating layer 4b is formed on the surface of each terminal 4a as shown in FIG. 8. Therefore, each chip component 3 is also soldered with the terminal 4a on the surface of which the gold plating layer 4b is formed.

Note that the connection terminal 3d of the chip component 3 is composed of, for example, an Ag/Pd electrode 3e, a Ni underplating layer 3f, and a solder plating layer 3g in this order from below. Also, the terminal 4a of the module board 4 is composed of a copper layer 4c, a Ni underplating layer 4d, and a gold plating layer 4b in this order from below. Further, the areas except the places where the solder connection portions 5 of the terminals 4a are formed are covered with an overcoating glass 4e, which is an insulating film (solder resist film).

More specifically, in the module board 4, the gold plating layer 4b is formed over the surfaces of all terminals 4a, and the chip components 3 are soldered to the gold plating layer 4b at the connection terminals 3d. In the semiconductor chip 2, the pads 2a thereof are connected to the gold wires 8, and the gold wires 8 are connected to the gold plating layer 4b of the terminals 4a.

In this case, it is preferable that the solder which does not contain lead (Pb) and mainly consists of, for example, tin (Sn) and antimony (Sb) is used for the solder connection portion 5 to which the chip component 3 is connected. In this manner, it is possible to mount the chip component 3 by the lead (Pb)-free solder. In addition, since the solder which does not contain lead is used also for the solder connection portion 5 of the semiconductor chip 2, the solder mounting by the lead-free solder can be achieved inside the radio frequency module 1.

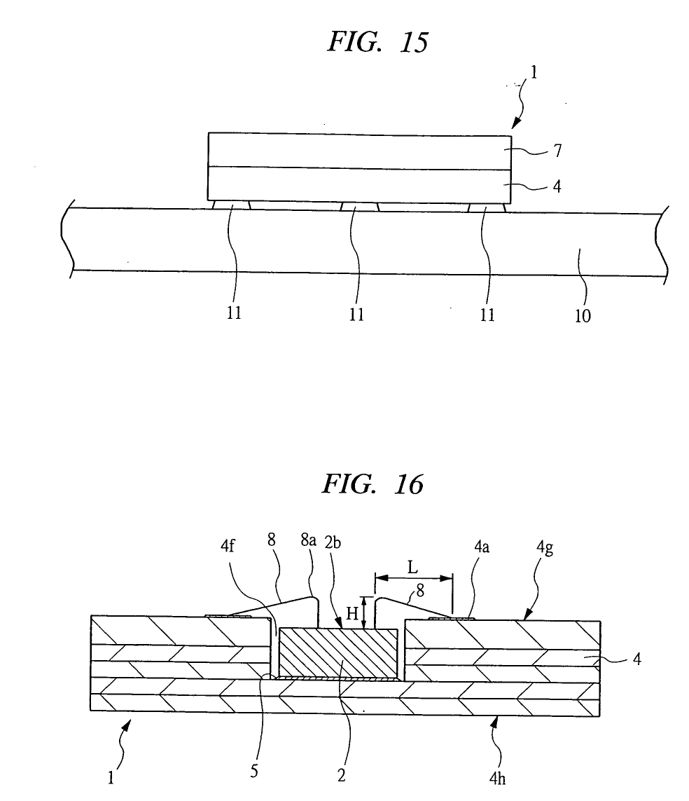

Also, as shown in FIG. 15, it is preferable to use the solder that does not contain lead (Pb) and mainly consists of, for example, tin (Sn), silver (Ag), and copper (Cu) for the solder-mounted part 11 when the radio frequency module 1 in this embodiment is mounted by solder on the mother board 10 which is a mounting board. By doing so, Pb-free mounting of the radio frequency module 1 can be realized.

As described above, by using the Pb-free solder mainly composed of tin (Sn) and antimony (Sb) for the solder-mounted components in the radio frequency module 1 and using the Pb-free solder mainly composed of tin (Sn), silver (Ag), and copper (Cu) for the solder-mounting of the radio-frequency module 1 to the mother board 10, it is possible to prevent the Pb-free solder from melting when the radio frequency module 1 is mounted because both the solders have a high melting point of 230° C. to 260° C.

As a result, it is possible to prevent the solders from flowing into the interface between the solder-mounted components and the resin, and also to prevent the short-circuit between the terminals of the solder-mounted components.

Next, a method of manufacturing the radio frequency module 1 in this embodiment will be described.

First, the module board 4 shown in FIG. 5 is prepared.

Note that a concave cavity 4f capable of storing the semiconductor chip 2 is formed in the surface 4g of the module board 4, and a plurality of terminals 4a which can be connected to the connection terminals 3d of the chip components 3 by solder are provided around the cavity. In addition, as shown in FIG. 3, a plurality of external terminals 1a are provided on the rear surface 4h.

Thereafter, solder paste is printed on each terminal 4a, and then, a plurality of surface-mounted components such as the semiconductor chip 2, chip component 3 and others are mounted by using the solder reflow. In this case, it is preferable to use the Pb-free solder that mainly consists of tin (Sn) and antimony (Sb).

After that, a wire bonding process is performed.

In this process, the pad 2a of the semiconductor chip 2 is wire-bonded with the terminal 4a on the module board 4 by the use of the gold wire 8.

This wire bonding is performed so that the wire height is 0.2 mm (200 μm) or lower, more preferably, 0.1 mm (100 μm) or higher to 0.2 mm.

On the other hand, the wire bonding is performed so that the wire length is 1.5 mm or shorter, more preferably, 0.5 mm or longer to 1.5 mm.

As an example, the wire height is 0.16 mm (160 μm) and the wire length is 1.2 mm.

After the wire bonding process, resin sealing process is performed.

In this process, the sealing section 7 is formed by the use of an insulating and low elastic resin such as silicone resin, and the semiconductor chip 2, the chip component 3 and the gold wire 8 are sealed by the sealing section 7.

Next, the radio frequency modules 1 of the modified examples in this embodiment will be described.

First, the radio frequency module 1 of the modified example shown in FIG. 16 has the structure in which the main surface 2b of the semiconductor chip 2 is recessed lower than the surface 4g of the module board 4. That is, the main surface 2b of the semiconductor chip 2 is lower than the surface 4g of the module board 4. This structure can be realized when the cavity 4f is comparatively deep.

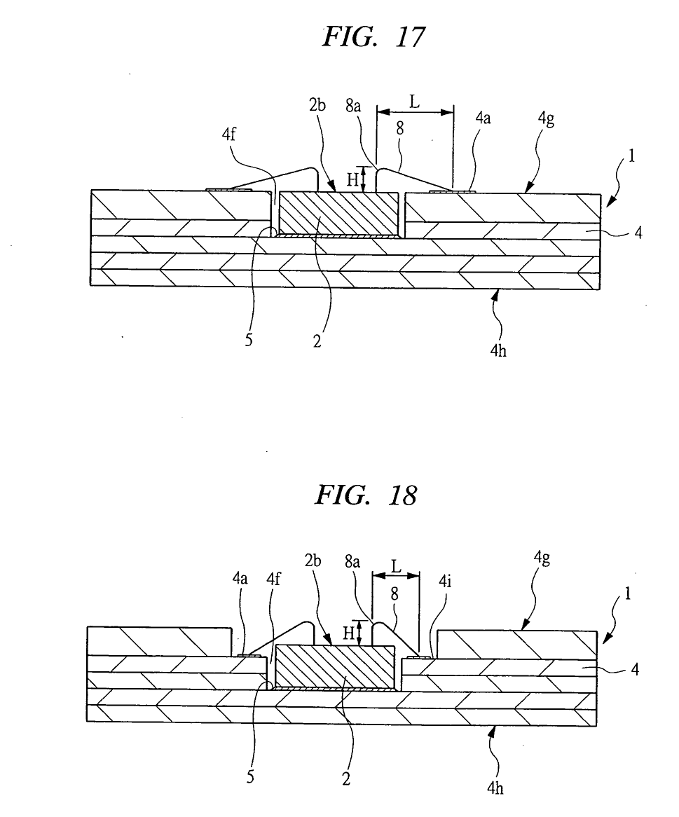

Also, the radio frequency module 1 of the modified example shown in FIG. 17 has the structure in which the main surface 2b of the semiconductor chip 2 has almost the same height as the surface 4g of the module board 4.

Further, the radio frequency module 1 of the modified example shown in FIG. 18 has the structure in which the cavity 4f has two steps. More specifically, the step 4i is formed on the wall of inner circumference of the cavity 4f where the semiconductor chip 2 is disposed and at the position having almost the same height as the main surface 2b of the semiconductor chip 2 and a little lower than the wire loop 8a, and the terminal 4a to which the gold wire 8 is connected is provided on the step 4i.

Also in this case, it is preferable to perform the wire bonding with using the semiconductor chip 2 side as the first bonding side in consideration of the bonding tool. However, it is allowable to perform the wire bonding with using the terminal 4a side as the first bonding side.

Note that in the radio frequency module 1 shown in FIG. 18, the height of the radio frequency module 1 can be lowered because all gold wires 8 can be contained in the cavity 4f having the two-step structure.

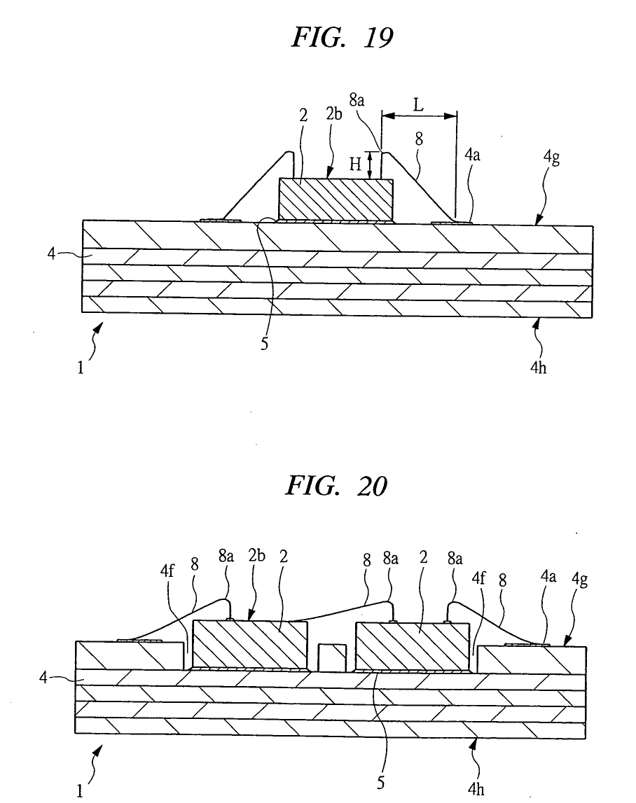

Further, the radio frequency module 1 shown in FIG. 19 has the structure in which the cavity 4f shown in FIG. 16 is not formed in the module board 4.

In the case of the module board 4 with no cavity therein, it is possible to make the structure of the board simpler, and therefore, the cost of the module board 4 can be reduced, and as a result, the cost of the radio frequency module 1 can be reduced.

Note that similar to the radio frequency module 1 shown in FIGS. 1 to 7, the radio frequency module 1 of modified examples shown in FIGS. 16 to 19 can be fabricated by setting similar conditions for the wire height, wire length, and the Pb-free solder.

More specifically, the wire bonding and the solder connection using the Pb-free solder described in this embodiment are also applicable to the radio frequency module 1 of the modified examples shown in FIGS. 16 to 19, and the same effects as those of the radio frequency module 1 shown in FIG. 1 to 7, for example, the prevention of the wire breakage can be achieved.

Next, the radio frequency module 1 of the modified example shown in FIG. 20 has the structure in which a plurality of concave cavities 4f are provided therein, the semiconductor chips 2 are mounted on each of the plurality of cavities 4f, and the semiconductor chips 2 are wire-bonded to each other.

Also, the radio frequency module 1 of the modified example shown in FIG. 21 has the structure in which the semiconductor chip 2 is wire-bonded to the chip component 3.

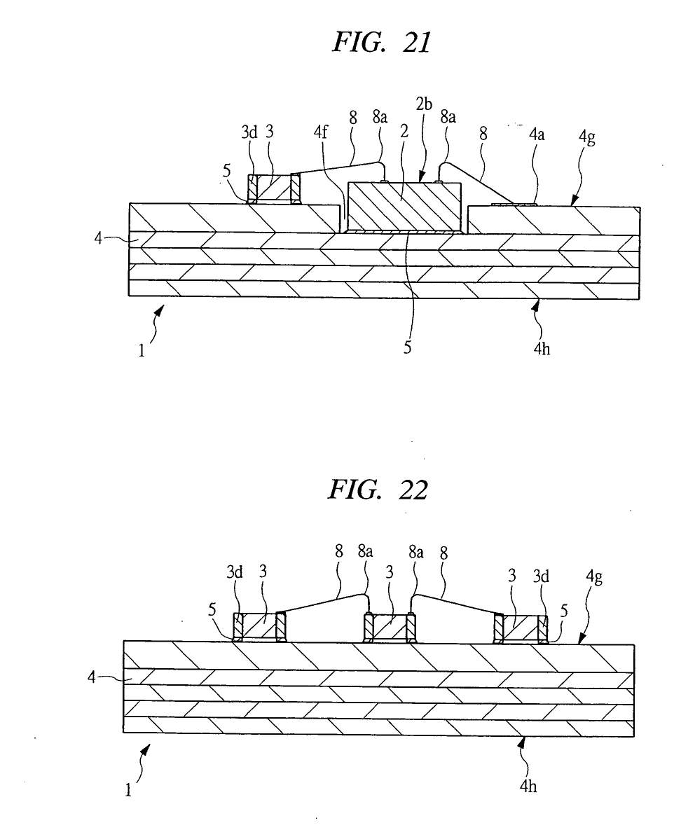

Further, the radio frequency module 1 of the modified example shown in FIG. 22 has the structure in which the chip components 3 are wire-bonded to each other.

Similar to the radio frequency module 1 shown in FIGS. 1 to 7, the radio frequency modules 10f the modified examples shown in FIGS. 20 to 22 can be fabricated by setting similar conditions for the wire height, wire length, and the Pb-free solder. As a result, the same effects as those of the radio frequency module 1 shown in FIG. 1 to 7, for example, the prevention of wire breakage can be achieved.

In the foregoing, the invention made by the inventors of the present invention has been concretely described based on the embodiment. However, it is needless to say that the present invention is not limited to the foregoing embodiment and various modifications and alterations can be made within the scope of the present invention.

For example, in the foregoing embodiment, the silicon eresin has been taken as an example of the low elastic resin. However, the elastic resin may be gel resin as long as the elastic modulus thereof is within the allowable range described in the embodiment.

Also, in the embodiment described above, the radio frequency module 1 has been taken as an example of the semiconductor device. However, the semiconductor device is replaceable with other module as long as it is provided with solder-mounted components, and the mounted components are wire-bonded and sealed with elastic resin.

Further, the mounted components are not limited to chip components and semiconductor chips, and can be other electronic components as long as they can be mounted by solder.

### INDUSTRIAL APPLICABILITY

As described above, the semiconductor device of the present invention is fabricated by using wire bonding and is suitable for a module product sealed with a low elastic resin, in particular, suitable for the radio frequency module in which semiconductor chips and chip components are mounted.

1. A semiconductor device comprising:
a semiconductor chip;
a wiring board over which said semiconductor chip is mounted;
a plurality of bonding wires for connecting surface electrodes of said semiconductor chip to terminals of said wiring board corresponding thereto; and
a sealing section in which said semiconductor chip and said plurality of bonding wires are covered and sealed with resin, said sealing section being formed of an insulating elastic resin,
wherein said elastic resin has an elastic modulus of 1 to 200 MPa at a temperature of 150° C. or higher, and a height of said bonding wire from a main surface of said semiconductor chip to a top of said bonding wire is 0.2 mm or less.

2. The semiconductor device according to claim 1,
wherein a height of said bonding wire from the main surface of said semiconductor chip to the top of said bonding wire is from 0.1 mm or more to 0.2 mm.

3. The semiconductor device according to claim 1,
wherein a wire horizontal distance from a bonding start point to an end point of said bonding wire is 1.5 mm or less.

4. The semiconductor device according to claim 3,
wherein said wire horizontal distance is from 0.5 mm to 1.5 mm.

5. The semiconductor device according to claim 1,
wherein said elastic resin is silicone resin.

6. The semiconductor device according to claim 1,
wherein chip components having connection terminals formed on both ends thereof are connected to said wiring board by solder, and said solder is mainly comprised of tin (Sn) and antimony (Sb).

7. The semiconductor device according to claim 1,
wherein chip components having connection terminals formed on both ends thereof are connected to said wiring board by solder, and said solder does not contain lead (Pb).

8. The semiconductor device according to claim 1,
wherein said elastic resin has an elastic modulus of 5 to 10 MPa at a temperature of 150° C. or higher.

9. The semiconductor device according to claim 1,
wherein a recess is formed in said wiring board and said semiconductor chip is disposed in said recess.

10. A semiconductor device comprising:
a semiconductor chip;
a wiring board over which said semiconductor chip is mounted;
a plurality of bonding wires for connecting surface electrodes of said semiconductor chip to terminals of said wiring board corresponding thereto; and
a sealing section in which said semiconductor chip and said plurality of bonding wires are covered and sealed with resin, said sealing section being formed of a silicone resin which is an insulating elastic resin with an elastic modulus of 1 to 200 MPa at a temperature of 150° C. or higher,
wherein a height of said bonding wire from a main surface of said semiconductor chip to a top of said bonding wire is 0.2 mm or less, and a wire horizontal distance from a bonding start point to an end point of said bonding wire is 1.5 mm or less.

11. A semiconductor device comprising:
a semiconductor chip;
a wiring board over which said semiconductor chip is mounted;
a plurality of bonding wires for connecting surface electrodes of said semiconductor chip to terminals of said wiring board corresponding thereto; and
a sealing section in which said semiconductor chip and said plurality of bonding wires are covered and sealed with resin, said sealing section being formed of an insulating elastic resin,
wherein said elastic resin has an elastic modulus of 1 to 200 MPa at a temperature of 150° C. or higher, and a height of said bonding wire from a bonding start point to a top of said bonding wire is 0.2 mm or less.

12. The semiconductor device according to claim 11,
wherein a wire horizontal distance from a bonding start point to an end point of said bonding wire is 1.5 mm or less.

13. A semiconductor device comprising:
a semiconductor chip;
a wiring board over which said semiconductor chip is mounted;
a plurality of bonding wires for connecting surface electrodes of said semiconductor chip to terminals of said wiring board corresponding thereto, said bonding wire having a height of 0.2 mm or less from a main surface of said semiconductor chip to a top of said wire; and
a sealing section in which said semiconductor chip and said plurality of bonding wires are covered and sealed with resin, said sealing section being formed of an insulating elastic resin with an elastic modulus of 1 to 200 MPa at a temperature of 150° C. or higher,
wherein said semiconductor device is connected to a mounting board by solder.

14. The semiconductor device according to claim 13,
wherein a wire horizontal distance from a bonding start point to an end point of said bonding wire is 1.5 mm or less.

15. The semiconductor device according to claim 13,
wherein said semiconductor device is connected to said mounting board by solder containing no lead (Pb).

16. The semiconductor device according to claim 13,
wherein said semiconductor device is connected to said mounting board by solder which is mainly comprised of tin (Sn), silver (Ag), and copper (Cu).
